(19) United States
(12) Patent Application Publication
(10) Pub. No.: US 2010/0002364 A1
(43) Pub. Date: Jan. 7, 2010

(54) HOUSING ASSEMBLY

(75) Inventors: ZHI-GANG ZOU, Shenzhen City (CN); ZHI-GANG PENG, Shenzhen City (CN); QING-BIN ZENG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/481,683

(22) Filed: Jun. 10, 2009

(30) Foreign Application Priority Data
Jul. 4, 2008 (CN) 200810302538.2

(51) Int. Cl. H05K 5/00

(52) U.S. Cl. 361/679.01

(57) ABSTRACT

A housing assembly is provided including a housing and a transparent display protective panel. The housing includes two parallel sides which defines two securing slots respectively. The two securing slots face and align with each other. The transparent display protective panel is secured into the two securing slots.

### BACKGROUND

1. Technical Field

The present disclosure relates to housing assemblies, and particularly to a housing assembly for a portable electronic device.

2. Description of Related Art

Typically, a housing assembly for portable electronic devices includes a housing, a display panel, and a display protective panel. The housing defines a display window. The display panel and the display protective panel are secured within the housing and aligned with the display window. The display protective panel is directly adhered to the housing above the display panel. Thus, the display panel can be protected by the display protective panel. However, the adherence of the display protective panel and the housing may deteriorate over time, then the display protective panel cannot be positioned precisely on the housing and may even be detached from the housing.

Therefore, there is room for improvement within the art.

### BRIEF DESCRIPTION OF THE DRAWING

Many aspects of the new housing assembly can be better understood with reference to the following drawings. The components in the drawings are not necessarily drawn to scale, the emphasis instead being placed upon clearly illustrating the principles of the new housing assembly. Moreover, in the drawings, like reference numerals designate corresponding parts throughout the several views.

FIG. 1 is an exploded, isometric view of a housing assembly according to an exemplary embodiment.

FIG. 2 is an assembled view of the housing assembly shown in FIG. 1.

FIG. 3 is a top view of the housing assembly shown in FIG. 2.

### DETAILED DESCRIPTION

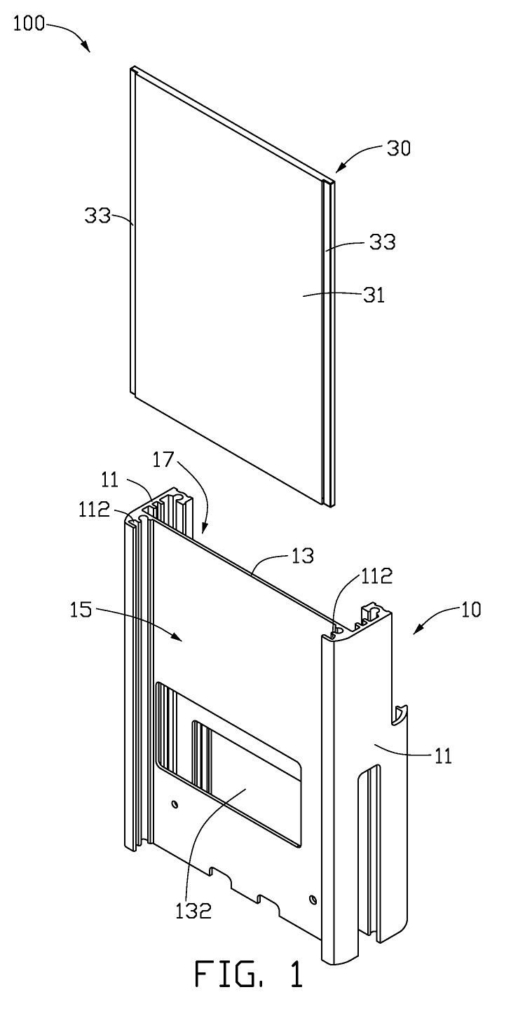

FIGS. 1-3 show an exemplary housing assembly 100 of a portable electronic device including a housing 10 and a display protective panel 30. Referring to FIG. 1, the housing 10 includes two parallel sides 11 and a middle board 13 connecting the two sides 11. The two sides 11 and the middle board 13 cooperatively define a securing space 15 and a mounting space 17. The securing space 15 and the mounting space 17 are oppositely arranged on the opposite sides of the middle board 13. The securing space 15 is used to secure a display panel and the display protective panel 30 therein. The mounting space 17 is used to mount electronic components of the portable electronic device therein.

Each of the two sides 11 defines a generally U-shaped securing slot 112 along the middle board 13 for securing the display protective panel 30 therein. The two securing slots 112 are spaced from the middle board 13, facing and aligning with each other. The middle board 13 defines a through hole 132 e.g., for allowing wires electronically connecting the display panel and the electronic components to pass through.

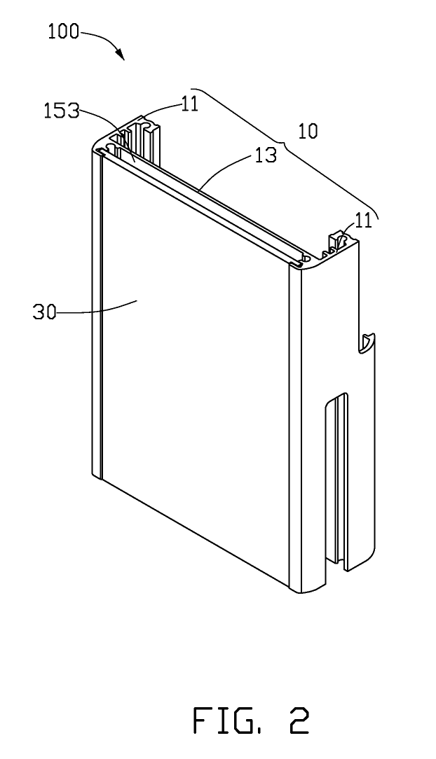

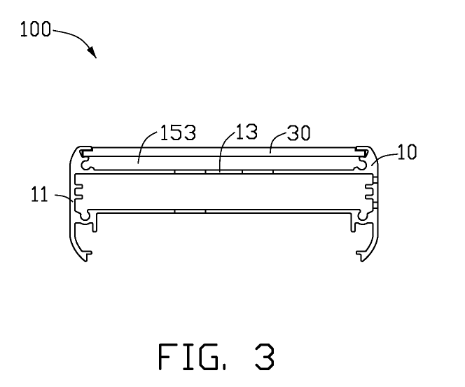

Referring further to FIGS. 2 and 3, the display protective panel 30 is transparent including a main panel portion 31 and two side panel portions 33. The two side panel portions 33 are parallel to each other on the two opposite sides of the main panel portion 31. The two side panel portions 33 are thinner than the main panel portion 31, so that the display protective panel 30 can be secured to the securing space 10 by the two side panel portions 33 being slidably received in and fixed (e.g., by hot-melted) to the two securing slots 112. After the above securing, the display protective panel 30, the two sides 11, and the middle board 13 enclose an accommodating space 153 for accommodating the display panel.

It is to be understood, however, that even through numerous characteristics and advantages have been set forth in the foregoing description of embodiments, together with details of the structure and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing assembly, comprising:
a housing comprising two parallel sides, the two sides defining two securing slots respectively, the two securing slots facing and aligning with each other; and
a transparent display protective panel secured into the two securing slots.

2. The housing assembly as claimed in claim 1, wherein the housing further comprises a middle board connecting the two sides, the two sides and the middle board cooperatively defines a securing space, and the display protective panel is secured into the securing space.

3. The housing assembly as claimed in claim 2, wherein the display protective panel comprises a main panel portion and two side panel portions on the two opposite ends of the main panel portion, the two side panel portions configured for being slidably received and fixed in the securing slots.

4. The housing assembly as claimed in claim 3, wherein the two side panel portions are parallel arranged and thinner than the main panel portion.

5. The housing assembly as claimed in claim 3, wherein the display protective panel, the sides and the middle board enclose an accommodating space.

6. The housing assembly as claimed in claim 2, wherein the middle board defines a through hole.

7. The housing assembly as claimed in claim 2, wherein the sides and the middle board cooperatively further defines and a mounting space, and the securing space and the mounting space are oppositely arranged on the two sides of the middle board.

8. A housing assembly for a portable electronic device, comprising:
a housing including two parallel sides and a middle board connecting the two sides, the middle board located between the two sides, each of the two sides defining a securing slot along the middle board; and
a transparent display protective panel slidably received and fixed into the two securing slots distal to the middle board.

9. The housing assembly as claimed in claim 8, wherein the two securing slots face and align with each other.

10. The housing assembly as claimed in claim 8, wherein the sides and the middle board cooperatively defines a securing space and a mounting space, and the securing space and the mounting space are oppositely arranged on the two sides.

11. The housing assembly as claimed in claim 10, wherein the sides, the transparent display protective panel and the middle board enclose an accommodating space within the securing space.

12. The housing assembly as claimed in claim 11, wherein the display protective panel comprises a main panel portion and two side panel portions on the two opposite ends of the main panel portion, the two side panel portions configured for being slidably received and fixed in the securing slots.

13. The housing assembly as claimed in claim 8, wherein the middle board defines a through hole.
